(19) United States
(12) Patent Application Publication
(10) Pub. No.: US 2006/0131574 A1
(43) Pub. Date: Jun. 22, 2006

(54) Nanowire sensor and method of manufacturing the same

(76) Inventors: Han Young Yu, Daejeon-city (KR); Ung Hwan Pi, Daejeon-city (KR); Chan Woo Park, Daejeon-city (KR); Sung Yool Choi, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/182,572

(22) Filed: Jul. 15, 2005

(30) Foreign Application Priority Data
Dec. 16, 2004 (KR) 10-2004-0107251

(51) Int. Cl. H01L 21/66; H01L 23/58

(52) U.S. Cl. 257/48; 977/920; 977/880; 438/18

(57) ABSTRACT

Provided are a nanowire sensor and a method of manufacturing the same. The nanowire sensor includes: a sensing target system comprising a target element to be detected; two electrodes separated from each other contained in the sensing target system; vanadium oxide (V₂O₅) nanowires incorporated in the sensing target system and attached to the two electrodes; and a measuring unit for measuring a change in resistance of the nanowires as the nanowires detect the target element.

This application claims the benefit of Korean Patent Application No. 10-2004-0107251, filed on Dec. 16, 2004, in the Korean Intellectual Property Office, the disclosure of which is incorporated herein in its entirety by reference.

### BACKGROUND OF THE INVENTION

1. Field of the Invention

The present invention relates to a detection sensor, and more particularly, to a sensor using vanadium oxide (V₂O₅) nanowires and a method of manufacturing the same.

2. Description of the Related Art

Detection sensors detect a specific element in a fluid, such as a gas and/or a liquid, or measure a partial pressure of a specific element. Detection sensors measure a degree of vacuum generated in a vacuum equipment or a vacuum chamber or find a location of leakage in the vacuum equipment or the vacuum chamber. Further, detection sensors measure a pressure of a fluid, such as a gas and/or a liquid and a concentration of a specific element in the fluid, etc. Various types of detection sensors using various principles have been developed.

It is known that an inert gas, such as helium (He) gas, or an inert element dose not react with other substances, and thus, a detection sensor for detecting the inert element cannot be easily developed. In order to determine whether the He gas is present or absent, a conventional method of recognizing a He gas by measuring a mass using, for example, a mass spectrometer, was suggested.

Accordingly, there is a need to develop a detection sensor which can detect whether various elements, including inert elements, are present or absent and can measure a degree of vacuum in a vacuum state and/or detect a flow of a fluid, including a pressure, using this detection performance.

### SUMMARY OF THE INVENTION

The present invention provides a sensor which can detect whether various elements, including inert elements, are present or absent, the sensor using vanadium oxide (V₂O₅) nanowires, and a method of manufacturing the same.

According to an aspect of the present invention, there is provided a nanowire sensor including: a sensing target system including a target element to be detected; two electrodes separated from each other contained in the sensing target system; vanadium oxide (V₂O₅) nanowires incorporated in the sensing target system and attached to the two electrodes; and a measuring unit for measuring a change in resistance of the nanowires as the nanowires detect the target element.

The target element to be detected may be helium (He).

The target element to be detected may be elements of atmospheric components contained in the atmosphere.

The target element to be detected may be oxygen (O₂), nitrogen (N₂), water (H₂O), or hydrogen (H₂).

The sensing target system may be a vacuum system or a system including a liquid phase or a gas phase.

The measuring unit may measure the change in resistance of the nanowires, thereby measuring a partial pressure or a concentration of the target element in the sensing target system.

The measuring unit may measure the change in resistance of the nanowires, thereby measuring a degree of vacuum or a change in pressure in the sensing target system.

The sensing target system may be a flow of a gas or fluid, the measuring unit measures the change in resistance of the nanowires, thereby measuring a change in pressure of the flow.

According to another aspect of the present invention, there is provided a method of manufacturing of a nanowire sensor, including: providing two electrode separated from each other; introducing V₂O₅ nanowires to be suspended between the two electrodes; applying an alternating voltage between the two electrodes such that the nanowires are arranged separated from each other due to the applied alternating current electric field; attaching the arranged nanowires to the two electrodes to be bridged between the two electrodes; and electrically connecting the two electrodes to a measuring unit.

According to still another aspect of the present invention, there is provided a method of manufacturing a nanowire sensor, including: preparing a solution in which V₂O₅ nanowires are dispersed; introducing the solution on and between two electrodes; applying an alternating voltage between the two electrodes such that the nanowires dispersed in the solution are arranged to be bridged between the two electrodes and separated from each other, due to the applied alternating current electric field; evaporating a solvent in the solution; attaching the arranged nanowires to the two electrodes; and electrically connecting the two electrodes to a measuring unit.

The above nanowire sensor can detect effectively inert gas elements, such as He, and thus, can be used to measure a degree of vacuum or detect a vacuum leakage, etc.

### BRIEF DESCRIPTION OF THE DRAWINGS

The above and other features and advantages of the present invention will become more apparent by describing in detail exemplary embodiments thereof with reference to the attached drawings in which:

FIG. 1A is a scanning electron microscope (SEM) photo of a nanowire sensor according to an embodiment of the present invention;

FIG. 1B is a schematic view of a nanowire sensor according to an embodiment of the present invention;

FIG. 2 illustrates graphs of voltage (V)—current (I) measured in a vacuum system and in the atmosphere, using a nanowire sensor according to an embodiment of the present invention;

FIG. 3 is a graph of a change in conductivity measured using a nanowire sensor according to an embodiment of the present invention; and

FIG. 4 is a graph of a change in resistance as a nanowire sensor according to an embodiment of the present invention detects helium (He).

### DETAILED DESCRIPTION OF THE INVENTION

Hereinafter, embodiments of the present invention will be described in more detail with reference to the attached drawings. However, these embodiments are given for the purpose of illustration and are not intended to limit the scope of the invention.

In an embodiment of the present invention, there is a sensor which can detect an inert gas, including helium (He) gas which cannot be detected using a conventional sensor, a degree of vacuum, and a flow of a fluid, including a pressure, is provided. Two-probe electrodes or, when necessary, four-probe electrodes are divided into two groups and vanadium oxide (V₂O₅) nanowires are arranged between the electrodes to be substantially connected to the electrodes. Then, one of the electrodes is electrically connected to a source node and the other is electrically connected to a drain node and a current between the source node and the drain node is measured, and thus, a resistance can be obtained. A resistance in a normal atmosphere, a resistance in a vacuum, a resistance when a He gas is injected into a sensing target system, and a resistance when pressures of other gases are changed, differ from each other, and thus, the nanowire sensor can detect a flow of a pressure and a concentration of a gas and/or a liquid.

The changes in the amounts of the gas and liquid present in the air can be detected using the high sensitivity of the sensor, and thus, information on the individual liquid and/or gas can be individualized.

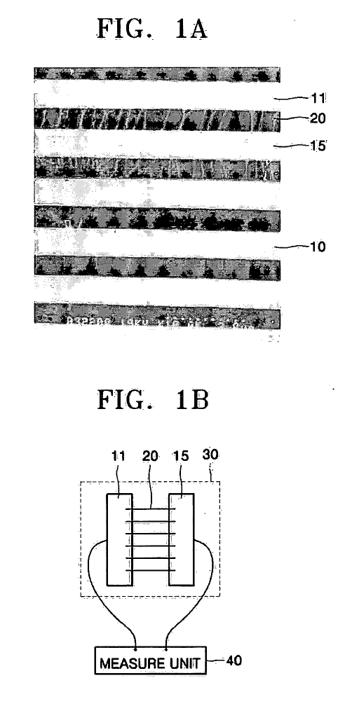

FIG. 1A is a scanning electron microscope (SEM) photo of a nanowire sensor according to an embodiment of the present invention. FIG. 1B is a schematic view of a nanowire sensor according to an embodiment of the present invention.

Referring to FIG. 1A, in the nanowire sensor, V₂O₅ nanowires 20 are arranged between two electrodes 11 and 15 and then, electrically connected to the two electrodes 11 and 15. The V₂O₅ nanowires 20 are arranged and attached to the two electrodes 11 and 15 using an alternating current electric field between the two electrodes 11 and 15 and another electrode 10 below the two electrodes 11 and 15. A voltage is applied between the two electrodes 11 and 15 to which the arranged V₂O₅ nanowires 20 are attached and a current flowing at this time is read. Referring to FIG. 1B, the nanowire sensor may comprise two electrodes 11 and 15 separated from each other in a sensing target system 30 which comprises a target element to be detected, for example, He, and V₂O₅ nanowires 20 incorporated into the sensing target system 30 and each having its both ends substantially attached between the two electrodes 11 and 15.

In this case, a source node and a drain node are attached to the two electrodes 11 and 15, respectively, and extended outward to be connected to a measuring unit 40. The measuring unit 40 applies a voltage between the two electrodes 11 and 15 and, as the V₂O₅ nanowires 20 detect the target element, the measuring unit 40 detects a change in current flowing the V₂O₅ nanowires 20, thereby detecting a change in resistance of the V₂O₅ nanowires 20.

The nanowire sensor may be manufactured using a method comprising preparing a solution in which V₂O₅ nanowires 20 are dispersed. Specifically, V₂O₅ nanowires 20 are formed and dispersed in a solvent to prepare the solution in which V₂O₅ nanowires 20 are dispersed. Next, the solution is dropped on the two electrodes 11 and 15 and the electrode 10 below the two electrodes 11 and 15 illustrated in FIG. 1A and also, between the electrodes 10, 11, and 15. When the solution is introduced on the two electrodes 11 and 15 and between the two electrodes 11 and 15, an alternating current voltage is applied between the electrodes 11 and 15. The V₂O₅ nanowires 20 in the dropped solution are arranged to be bridged between the two electrodes 11 and 15 and separated from each other, due to the applied alternating current voltage. At this time, the V₂O₅ nanowires 20 are arranged substantially parallel to each other, as demonstrated by the SEM photo of FIG. 1A.

Then, the solvent in the solution is evaporated and thus, the arranged nanowires may be attached to all the electrodes between the electrodes 11 and 10. Next, a source node and a drain node are attached to the two electrodes 11 and 15, respectively, and electrically connected to the measuring unit 40 to complete the nanowire sensor.

The V₂O₅ nanowires 20 are incorporated into the sensing target system 30 to detect the target element in the sensing target system 30. The target element to be detected may be an inert gas element, for example, He, or elements of atmospheric components and/or other components contained in the atmosphere. For example, the target element to be detected may be oxygen (O₂), nitrogen (N₂), water (H₂O), or hydrogen (H₂).

The measuring unit 40 can detect a change in resistance of the nanowires 20. Thus, the measuring unit 40 can measure a partial pressure or a concentration of the target element, and changes thereof in the sensing target system 30, such as a vacuum system, for example, an inside of a vacuum chamber, a normal atmosphere, a system in a liquid state, or a system in which a liquid is introduced and components of the liquid are evaporated to the atmosphere. Also, the measuring unit 40 can measure a degree of vacuum or a change in pressure in the sensing target system 30, and when the sensing target system 30 is a flow of a gas or fluid, the measuring unit 40 can measure a change in pressure of the flow.

The results of a degree of vacuum measured using a nanowire sensor according to an embodiment of the present invention will be described.

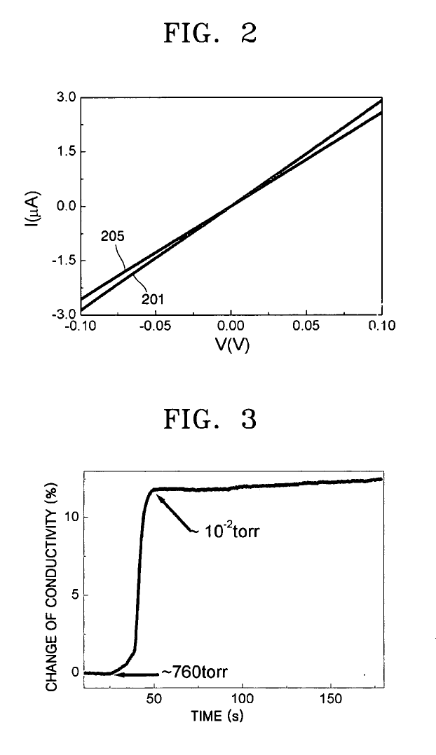

FIG. 2 illustrates graphs of voltage (V)—current (I) measured in a vacuum system and in the atmosphere, using a nanowire sensor according to an embodiment of the present invention.

The nanowire sensor is introduced in a vacuum chamber and two electrodes 11 and 15 (see FIG. 1A) are connected to an outer measuring unit 40 (see FIG. 1B), and then changes in resistance are measured for the case in which the vacuum chamber is in a vacuum state and the case in which the vacuum chamber is under the atmosphere. V-I graphs illustrating the changes in resistance are shown in FIG. 2. Reference numeral 201 denotes a V-I graph measured at a degree of vacuum of about 1×10⁻² torr and reference numeral 205 denotes a V-I graph measured in the atmosphere. As seen from FIG. 2, the resistance value in a vacuum state is lower than the resistance value in the atmosphere.

FIG. 3 is a graph of a change in conductivity measured using a nanowire sensor according to an embodiment of the present invention.

Referring to FIG. 3, the change in conductivity is measured while evacuating a chamber having an internal air pressure of 760 torr at a constant voltage. That is, the change in conductivity is obtained by normalizing a conductivity (S) based on a conductivity (S₀) in the air. It is confirmed from FIG. 3 that the conductivity is sharply increased when the vacuum system is formed by turning on a vacuum pump.

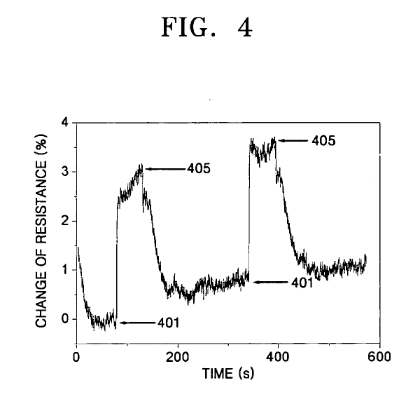

FIG. 4 is a graph of a change in resistance as a nanowire sensor according to an embodiment of the present invention detects He.

Referring to FIG. 4, a resistance 401 measured at a degree of vacuum of 1×10⁻² torr is different from a resistance 405 measured when a pressure is increased to 760 torr by injecting a He gas into a sensing target system. That is, a change in resistance is detected as the He gas is injected. The result of FIG. 4 shows that the nanowire sensor according to an embodiment of the present invention is very useful to obtain information on whether an inert element such as He is present or absent.

Thus, in the embodiments of the present invention, it can be seen that the nanowire sensor using the V₂O₅ nanowires can operate as a sensor for an inert gas and a degree of vacuum, based on the change in conductivity measured. That is, as the degree of vacuum gradually decreases from an atmospheric pressure, the conductivity gradually increases and when an inert gas is introduced into the sensor at the decreased degree of vacuum, the conductivity increases again. These behaviors vary according to the types of gas injected and especially, show that the sensor can respond to an inert gas, which does not chemically react with other substances, as well as a normal gas. Thus, the nanowire sensor according to the present invention can substitute a conventional He detection instrument and can detect other inert and active gases.

The nanowire sensor according to the present invention can find a location of leakage in a vacuum equipment generally used in a high vacuum. That is, the nanowire sensor according to the present invention can be used to find where a vacuum is leaked when the vacuum equipment is not evacuated even at a high vacuum state, by allowing a He gas to flow in the vacuum camber.

According to the present invention, a nanowire sensor which has a smaller size and much simpler He detection mechanism than a conventional helium detection apparatus using mass spectroscopy is suggested. The nanowire sensor can be manufactured in a very small size and since the nanowires has a wide detection surface using the nanowires, the nanowire sensor can easily detect the leakage of the He gas in a high vacuum state.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nanowire sensor comprising:
a sensing target system comprising a target element to be detected;
two electrodes separated from each other contained in the sensing target system;
vanadium oxide (V₂O₅) nanowires incorporated in the sensing target system and attached to the two electrodes; and
a measuring unit for measuring a change in resistance of the nanowires as the nanowires detect the target element.

2. The nanowire sensor of claim 1, wherein the target element to be detected is helium (He).

3. The nanowire sensor of claim 1, wherein the target element to be detected is elements of atmospheric components contained in the atmosphere or other components contained in the atmosphere.

4. The nanowire sensor of claim 1, wherein the target element to be detected is oxygen (O₂), nitrogen (N₂), water (H₂O), or hydrogen (H₂).

5. The nanowire sensor of claim 1, wherein the sensing target system is a vacuum system or a system comprising a liquid phase or a gas phase.

6. The nanowire sensor of claim 1, wherein the measuring unit measures the change in resistance of the nanowires, thereby measuring a partial pressure or a concentration of the target element in the sensing target system.

7. The nanowire sensor of claim 1, wherein the measuring unit measures the change in resistance of the nanowires, thereby measuring a degree of vacuum or a change in pressure in the sensing target system.

8. The nanowire sensor of claim 1, wherein when the sensing target system is a flow of a gas or fluid, the measuring unit measures the change in resistance of the nanowires, thereby measuring a change in pressure of the flow.

9. A method of manufacturing of a nanowire sensor, comprising:
providing two electrode separated from each other;
introducing V₂O₅ nanowires to be suspended between the two electrodes;
applying an alternating voltage between the two electrodes such that the nanowires are arranged separated from each other due to the applied alternating current electric field;
attaching the arranged nanowires to the two electrodes to be bridged between the two electrodes; and
electrically connecting the two electrodes to a measuring unit.

10. A method of manufacturing a nanowire sensor, comprising:
preparing a solution in which V₂O₅ nanowires are dispersed;
introducing the solution on and between two electrodes;
applying an alternating voltage between the two electrodes such that the nanowires dispersed in the solution are arranged to be bridged between the two electrodes and separated from each other, due to the applied alternating current electric field;
evaporating a solvent in the solution;
attaching the arranged nanowires to the two electrodes; and
electrically connecting the two electrodes to a measuring unit.
